(19) United States
(12) Patent Application Publication
(10) Pub. No.: US 2011/0211323 A1
(43) Pub. Date: Sep. 1, 2011

(54) CIRCUIT BOARD, SEMICONDUCTOR DEVICE, AND METHOD OF MANUFACTURING THE SEMICONDUCTOR DEVICE

(75) Inventor: Norichika Unriin, Mie (JP)

(73) Assignee: Kabushiki KaishaToshiba, Tokyo (JP)

(21) Appl. No.: 13/018,912

(22) Filed: Feb. 1, 2011

(30) Foreign Application Priority Data
Mar. 1, 2010 (JP) 2010-044594

(51) Int. Cl. H05K 7/00; H05K 3/30

(52) U.S. Cl. 361/783; 361/760; 29/832

(57) ABSTRACT

According to one embodiment, a circuit board includes: a substrate on which circuit patterns are formed, a first surface of the substrate being formed substantially flat; and a solder resist film that covers the first surface of the substrate. The solder resist film assumes, as a whole, a convex shape in which the thickness of the solder resist film in the center of the substrate is larger than the thickness of the solder resist film in the periphery of the substrate.

### CROSS-REFERENCE TO RELATED APPLICATIONS

This application is based upon and claims the benefit of priority from the prior Japanese Patent Application No. 2010-44594, filed on Mar. 1, 2010; the entire contents of which are incorporated herein by reference.

### FIELD

Embodiments described herein relate generally to a circuit board, a semiconductor device, and a method of manufacturing the semiconductor device.

### BACKGROUND

In the past, a semiconductor device used while including a semiconductor memory chip such as a NAND flash memory, the semiconductor memory chip is mounted on a circuit board on which circuit patterns are formed. In such a semiconductor device, in some case, a plurality of semiconductor memory chips are stacked on the circuit board according to a request for high-density packaging.

In the circuit board, in some case, because of the circuit patterns, through-holes, or the like formed on the circuit board, a local recess is caused on a surface on which the semiconductor memory chip is mounted. In some case, because of this recess, air bubbles remain between the circuit board and the semiconductor memory chip bonded via a die attach film. The remaining air bubbles have large volume fluctuation due to a temperature change. Therefore, the semiconductor memory chip tends to peel off from the semiconductor board.

When a plurality of semiconductor memory chips are stacked, the thickness of each of the semiconductor memory chips is reduced according to limitation on the thickness of the semiconductor device itself. In general, in a semiconductor memory chip, different materials such as silicon, a silicon oxide film, and the like are combined. Therefore, in some case, deforming force to warp the semiconductor memory chip itself is caused in the semiconductor memory chip because of a difference among expansion coefficients of the materials. In the semiconductor memory chip reduced in thickness, force resisting this deforming force is weakened. Therefore, a warp tends to occur in the semiconductor memory chip itself. Because of this warp of the semiconductor memory chip itself, air bubbles also tend to remain between the semiconductor memory chip and the circuit board and the semiconductor memory chip also tends to peel off from the circuit board.

### BRIEF DESCRIPTION OF THE DRAWINGS

FIG. 1 is a cross sectional view of a sectional configuration of a semiconductor device according to a first embodiment;

FIG. 2 is a schematic plan view of a plane configuration of a circuit board;

FIG. 3 is a schematic sectional view of a sectional configuration of the circuit board shown in FIG. 2;

FIG. 4 is a plan view of a sheet substrate;

FIG. 5 is a plan view of a backup plate;

FIG. 6 is a flowchart for explaining a procedure of a manufacturing process for the semiconductor device;

FIG. 7 is a diagram for explaining the manufacturing process for the semiconductor device and is a cross sectional view of the sheet substrate;

FIG. 8 is a diagram for explaining the manufacturing process for the semiconductor device and is a cross sectional view of the sheet substrate; and

FIG. 9 is a diagram for explaining the manufacturing process for the semiconductor device and is a cross sectional view of the sheet substrate.

### DETAILED DESCRIPTION

In general, according to one embodiment, a circuit board includes: a substrate on which circuit patterns are formed, a first surface of the substrate being formed substantially flat; and a solder resist film that covers the first surface of the substrate. The solder resist film assumes, as a whole, a convex shape in which the thickness of the solder resist film in the center of the substrate is larger than the thickness of the solder resist film in the periphery of the substrate.

Exemplary embodiments of a circuit board, a semiconductor device, and a method of manufacturing the semiconductor device will be explained below in detail with reference to the accompanying drawings. The present invention is not limited to the following embodiments.

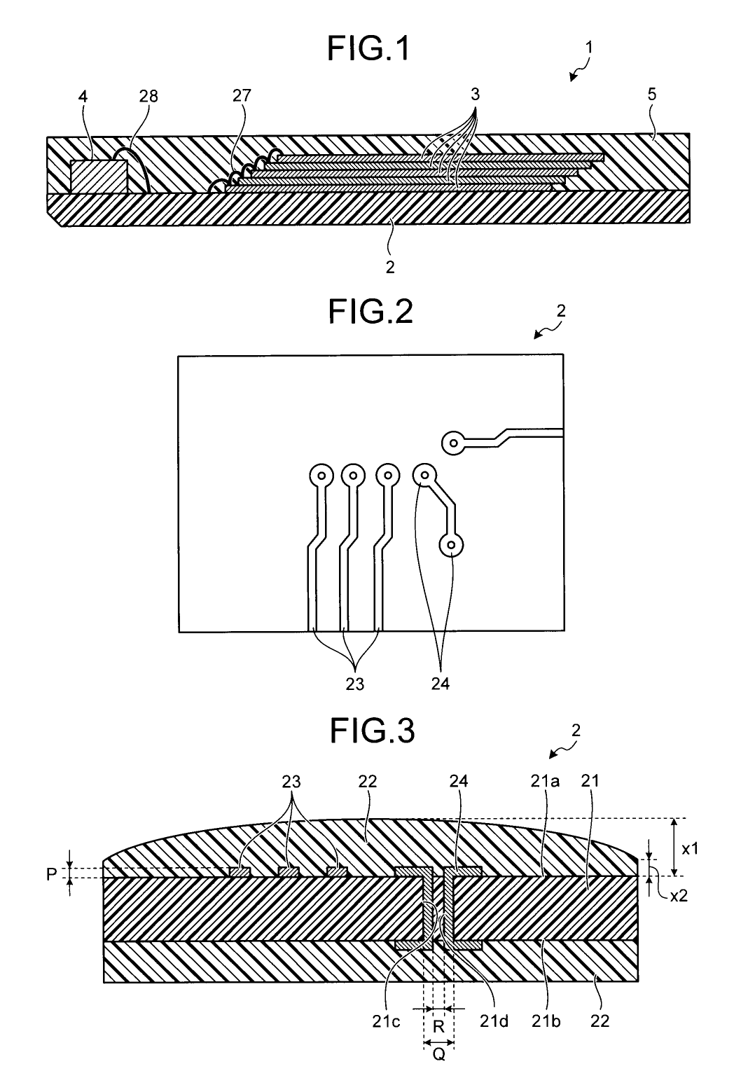

FIG. 1 is a cross sectional view of a sectional configuration of a semiconductor device according to a first embodiment. A semiconductor device 1 includes a circuit board 2, a semiconductor memory chip 3, a controller chip 4, and a resin mold section 5.

FIG. 2 is a schematic plan view of a plane configuration of the circuit board 2. FIG. 3 is a schematic sectional view of a sectional configuration of the circuit board 2 shown in FIG. 2. In FIGS. 2 and 3, for simplification of the drawings, only a part of circuit patterns 23 and the like formed on the circuit board 2 is shown. In the circuit board 2, for example, wiring networks are provided on the inside and the surface of an insulative resin board. The circuit board 2 functions as both an element mounting board and a terminal forming board. The circuit board 2 includes a substrate 21 and solder resist films 22. As the substrate 21, a substrate obtained by forming a resin material such as glass-epoxy resin or bismaleimide triazine (BT) resin in a thin plate shape is used. The circuit patterns 23 as the wiring networks and through-holes 24 are formed on the substrate. Both a front surface (a first surface) 21a and a rear surface (a second surface) 21b of the substrate 21 assume a substantially flat thin plate shape.

The circuit patterns 23 are formed of, for example, copper foil. Thickness P of the circuit patterns 23 is about 18 micrometers. Although not shown in detail in the figure, the substrate 21 is formed in a multilayer structure. The circuit patterns 23 are formed not only on the front surface 21a and the rear surface 21b of the substrate 21 but also on an inner layer surface of the substrate 21. Each of the through-holes 24 is formed by applying copper plating to the inner surface of a perforated hole 21c formed in the substrate 21. The circuit patterns 23 formed on different layers are electrically connected to one another via the copper plating applied to the through-hole 24. An inner diameter Q of the perforated hole 21c formed in the substrate 21 is about 0.2 millimeter. An inner diameter R of a perforated hole 21d after the application of the copper plating to the perforated hole 21c is about 0.1 millimeter. A part of the circuit patterns 23 is not covered by the solder resist film 22 and functions as a connection pad (not shown) for performing wire bonding.

The solder resist films 22 are formed to cover both the front surface 21a and the rear surface 21b of the substrate 21. Insulation properties among the circuit patterns 23 formed on the substrate 21 are maintained by the solder resist films 22. The solder resist film 22 formed on the front surface 21a side is formed to assume a convex shape as a whole. The solder resist film 22 is desirably formed in the convex shape in which a difference between thickness ×1 of the solder resist film 22 in the center of the substrate 21 and thickness ×2 of the solder resist film 22 in the periphery of the substrate 21 is 5 micrometers to 13 micrometers.

The semiconductor memory chip 3 is a memory element such as a NAND flash memory. A plurality of the semiconductor memory chips 3 are stacked on the solder resist film 22 formed on the front surface 21a side of the substrate 21. The semiconductor memory chip 3 in the bottom layer among the semiconductor memory chips 3 is bonded to the solder resist film 22 by a bonding material. As the bonding material, a thermosetting or photo-curable die attach film (an adhesive film) containing general polyimide resin, epoxy resin, acrylic resin, or the like as a main component is used.

The other semiconductor memory chips 3 are bonded in a step shape on the semiconductor memory chip 3 in the bottom layer bonded on the solder resist film 22, whereby the semiconductor memory chips 3 are stacked. An electrode pad provided on one side of the semiconductor memory chips 3 can be exposed by stacking the semiconductor memory chips 3 in the step shape. The exposed electrode pad is electrically connected (wiring-bonded) to the connection pad, which is formed on the circuit board 2, by a metal wire 27 such as an Au wire.

The controller chip 4 is mounted on the solder resist film 22 formed on the front surface 21a side of the substrate 21. The controller chip 4 selects, out of the semiconductor memory chips 3, the semiconductor memory chip 3 in which data is written and from which data is read out. The controller chip 4 performs writing of data in the selected semiconductor memory chip 3 and readout of data stored in the selected semiconductor memory chip 3. An electrode pad (not shown) is formed on the upper surface of the controller chip 4. The electrode pad and the connection pad of the circuit board 2 are wire-bonded by a metal wire 28. Electronic components such as a chip capacitor, a resistor, and an inductor are also mounted on the solder resist film 22 formed on the front surface 21a side of the substrate 21. However, the electronic components are not shown in the figure and detailed explanation of the electronic components is omitted.

The resin mold section 5 is formed by sealing the front surface of the circuit board 2 with a resin material. The resin mold section 5 forms an outer shell of the semiconductor device 1. The resin mold section 5 is formed at height for completely covering the semiconductor memory chips 3 and the controller chip 4. The resin mold section 5 is formed by covering the circuit board 2, on which the mounted components such as the semiconductor memory chips 3 are mounted, with a mold and injecting a softened resin material into the mold.

The solder resist film 22 is formed to assume one convex shape as a whole on the front surface 21a side of the substrate 21. Therefore, it is possible to suppress a local recess from being caused on the surface of the circuit board 2 on which the semiconductor memory chip 3 is bonded. This makes it possible to suppress generation of air bubbles when the semiconductor memory chip 3 is bonded to the circuit board 2 and improve reliability of bonding of the semiconductor memory chip 3.

The convex shape of the solder resist film 22 is formed along the warp of the bonding surface itself of the semiconductor memory chip 3. Therefore, it is possible to improve adhesiveness between the semiconductor memory chip 3 and the circuit board 2 and further improve the reliability of bonding.

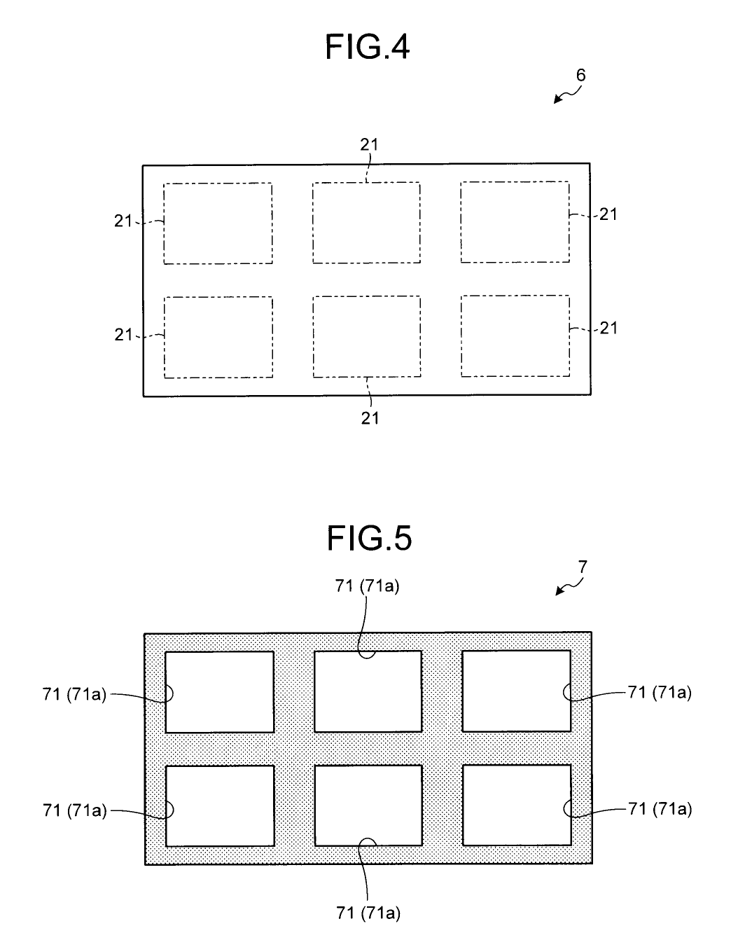

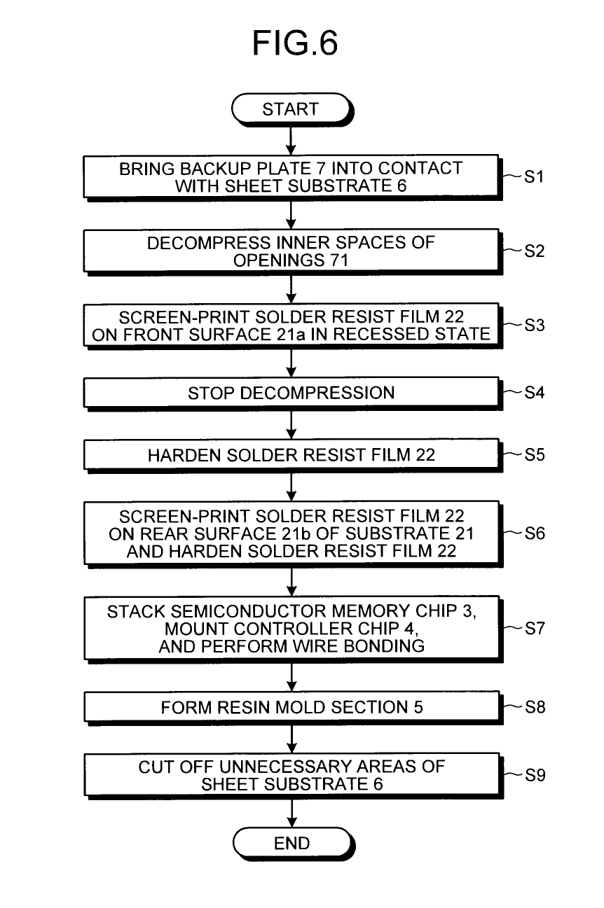

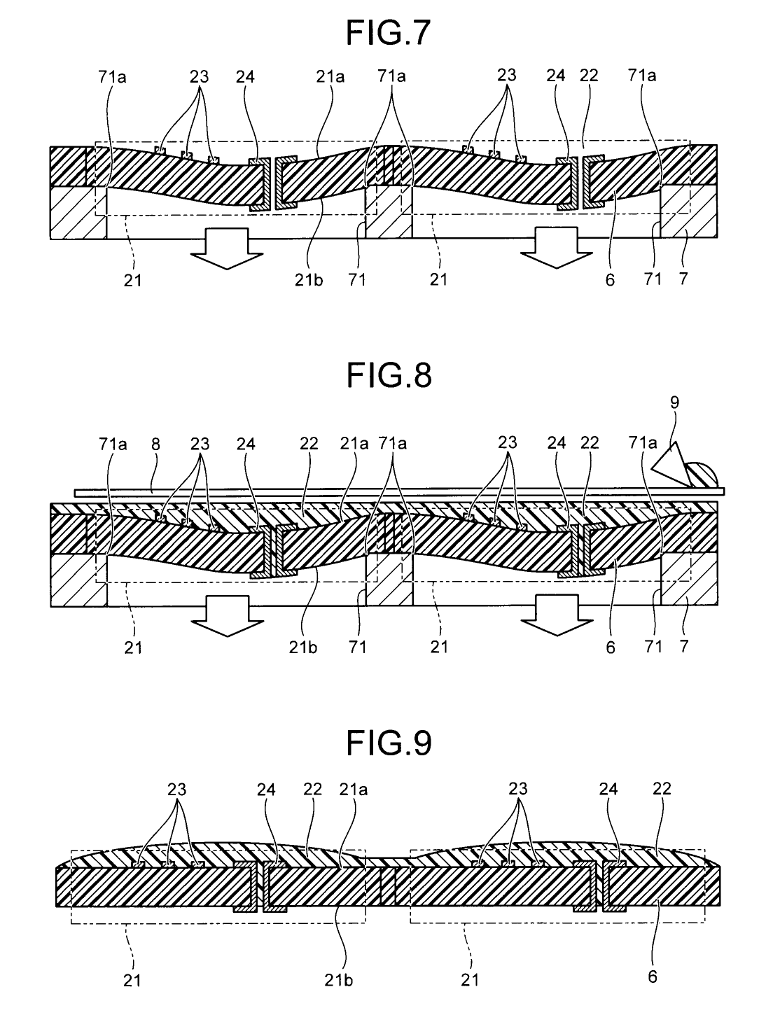

A manufacturing process for the semiconductor device 1 is explained below. FIG. 4 is a plan view of a sheet substrate. FIG. 5 is a plan view of a backup plate. FIG. 6 is a flowchart for explaining a procedure of the manufacturing process for the semiconductor device 1. FIGS. 7 to 9 are diagrams for explaining the manufacturing process for the semiconductor device 1 and are cross sectional views of the sheet substrate.

A sheet substrate 6 is used for manufacturing of the semiconductor device 1. As shown in FIG. 4, the sheet substrate 6 assumes a shape in which a plurality of the substrates 21 are integrally connected. It is possible to manufacture a plurality of the semiconductor devices 1 at a time by using the sheet substrate 6.

First, a backup plate (a frame member) 7 is brought into contact with the sheet substrate 6 (step S1). As shown in FIG. 5, the backup plate 7 is a frame member in which a plurality of openings 71 are formed. The openings 71 are formed to have a shape slightly smaller than the outer shape of the substrate 21. The backup plate 7 is brought into contact with the sheet substrate 6 such that opening edges 71a of the openings 71 come into contact with the periphery of the circuit board 2.

Inner spaces of the openings 71 formed in the backup plate 7 are connected to a not-shown suction apparatus. The air in the inner spaces of the openings 71 is sucked by the suction apparatus to decompress the inner spaces of the openings 71 (step S2). When the inner spaces of the openings 71 are decompressed, as shown in FIG. 7, the circuit board 2 bends and the front surface 21a side has a recessed shape.

Subsequently, screen printing is applied to the front surface 21a in the recessed state using a screen 8 and a squeegee 9 to form the surface of the solder resist film 22 as a surface as flat as possible (step S3). The solder resist film 22 is formed on the front surface 21a in the recessed state. Therefore, as shown in FIG. 8, it is possible to set the thickness of the solder resist film 22 in the center of the substrate 21 larger than the thickness of the solder resist film 22 in the periphery of the substrate 21.

The suction by the suction apparatus is stopped to stop the decompression (step S4). When the decompression is stopped, the recessed surface 21a of the substrate 21 is restored to the substantially flat shape. According to the restoration of the shape of the front surface 21a of the substrate 21, as shown in FIG. 9, the solder resist film 22 assumes one convex shape as a whole. Heat treatment is applied to the solder resist film 22 formed on the front surface 21a of the substrate 21 to harden the solder resist film 22 (step S5).

The solder resist film 22 is screen-printed on the rear surface 21b of the substrate 21 and hardened (step S6) (refer to FIG. 3 for a state in which the solder resist film 22 is formed on the rear surface 21b of the substrate 21). The semiconductor memory chip 3 is stacked on the solder resist film 22 formed on the front surface 21a side of the substrate 21, the controller chip 4 is mounted, and wire bonding is performed (step S7). The resin mold section 5 is formed on the substrate 21 to cover the front surface (step S8). Unnecessary areas of the sheet substrate 6 are cut off (step S9). Consequently, the singulated semiconductor device 1 is manufactured.

The semiconductor device 1 is manufactured by the process explained above. Therefore, if the solder resist film 22 is formed by general screen printing, it is possible to form the solder resist film 22 that assumes a convex shape as a whole and realize improvement of the adhesiveness between the circuit board 2 and the semiconductor memory chip 3 and improvement of the reliability of boding. The solder resist film 22 assumes the convex shape as a whole. Therefore, even when the solder resist film 22 is viewed on a cut surface rotated 90 degrees in the horizontal direction from a cut surface shown in FIG. 3, the thickness of the solder resist film 22 in the center of the substrate 21 is larger than the thickness of the solder resist film 22 in the periphery of the substrate 21.

The solder resist film 22 is hardened after the suction by the suction apparatus is stopped and the shape of the substrate 21 is restored. Therefore, it is possible to suppress cracks from being caused in the solder resist film 22 by deformation after the hardening.

A procedure of the manufacturing process for the semiconductor device 1 is not limited to the procedure shown as the flowchart in FIG. 6. For example, it is also possible to stack the semiconductor memory chip 3 and mount the controller chip 4 after cutting off the unnecessary areas of the sheet substrate 6, i.e., after performing the singulation of the circuit board 2.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the sprit of the inventions. The accompanying claims and their equivalents are intended to cover such forms or modifications as would fall within the scope and spirit of the inventions.

What is claimed is:

1. A semiconductor device comprising:
a circuit board including:
a substrate on which circuit patterns are formed, a first surface of the substrate being formed substantially flat; and
a solder resist film that covers the first surface of the substrate; and
a semiconductor chip provided on the solder resist film, wherein
the solder resist film assumes, as a whole, a convex shape in which thickness of the solder resist film in a center of the substrate is larger than thickness of the solder resist film in a periphery of the substrate.

2. The semiconductor device according to claim 1, wherein a difference between the thickness of the solder resist film in the center of the substrate and the thickness of the solder resist film in the periphery of the substrate is 5 micrometers to 13 micrometers.

3. The semiconductor device according to claim 1, wherein a plurality of the semiconductor chips are stacked in a step shape on the solder resist film.

4. The semiconductor device according to claim 1, wherein the semiconductor chip is a NAND flash memory.

5. The semiconductor device according to claim 4, further comprising a controller chip provided on the solder resist film.

6. The semiconductor device according to claim 1, further comprising a resin mold section that is formed on the solder resist film and covers the semiconductor chip.

7. A circuit board comprising:
a substrate on which circuit patterns are formed, a first surface of the substrate being formed substantially flat; and
a solder resist film that covers the first surface of the substrate, wherein
the solder resist film assumes, as a whole, a convex shape in which thickness of the solder resist film in a center of the substrate is larger than thickness of the solder resist film in a periphery of the substrate.

8. The circuit board according to claim 7, wherein a difference between the thickness of the solder resist film in the center of the substrate and the thickness of the solder resist film in the periphery of the substrate is 5 micrometers to 13 micrometers.

9. A method of manufacturing a semiconductor device comprising:
bringing a frame member, which comes into contact with a periphery of a substrate, into contact with a second surface on a rear side of a first surface of the substrate;
decompressing an inner space of the frame member to recess the first surface side of the substrate;
forming a solder resist film on the recessed first surface;
stopping the decompression of the inner space of the frame member to restore the first surface side of the substrate to a substantially flat shape; and
providing a semiconductor chip on the solder resist film.

10. The method of manufacturing the semiconductor device according to claim 9, wherein the solder resist film is formed by screen printing.

11. The method of manufacturing the semiconductor device according to claim 9, wherein the solder resist film is hardened after the first surface side of the substrate is restored to substantially the flat shape.

12. The method of manufacturing the semiconductor device according to claim 9, wherein a difference between thickness of the solder resist film in a center of the substrate and thickness of the solder resist film in a periphery of the substrate is 5 micrometers to 13 micrometers.

13. The method of manufacturing the semiconductor device according to claim 9, wherein a plurality of the semiconductor chips are stacked in a step shape on the solder resist film.

14. The method of manufacturing the semiconductor device according to claim 9, wherein the semiconductor chip is a NAND flash memory.

15. The method of manufacturing the semiconductor device according to claim 14, wherein a controller chip is provided on the solder resist film.

16. The method of manufacturing the semiconductor device according to claim 13, wherein a resin mold section that covers the semiconductor chip is formed on the solder resist film.
